(19) United States
(12) Patent Application Publication
(10) Pub. No.: US 2025/0240869 A1
(43) Pub. Date: Jul. 24, 2025

(54) ELECTRONIC DEVICE

(71) Applicant: Murata Manufacturing Co., Ltd., Nagaokakyo-shi (JP)

(72) Inventors: Akihito NAITO, Nagaokakyo-shi (JP); Koshi HIMEDA, Nagaokakyo-shi (JP)

(21) Appl. No.: 19/171,485

(22) Filed: Apr. 7, 2025

Related U.S. Application Data
(63) Continuation of application No. PCT/JP2023/036686, filed on Oct. 10, 2023.

(30) Foreign Application Priority Data
Oct. 14, 2022 (JP) 2022-165507

(51) Int. Cl. H05K 1/02

(52) U.S. Cl. CPC H05K 1/0204

(57) ABSTRACT

An electronic device that includes: a wiring board having a first main surface and a second main surface that face away from each other in a thickness direction; a first electronic component on the first main surface of the wiring board; a second electronic component on the second main surface of the wiring board; a first heat diffuser plate thermally connected to the first electronic component; a second heat diffuser plate thermally connected to the second electronic component; and a heat conductor extending through the wiring board in the thickness direction and thermally connected to the first heat diffuser plate and the second heat diffuser plate.

### CROSS REFERENCE TO RELATED APPLICATIONS

The present application is a continuation of International application No. PCT/JP2023/036686, filed Oct. 10, 2023, which claims priority to Japanese Patent Application No. 2022-165507, filed Oct. 14, 2022, the entire contents of each of which are incorporated herein by reference.

### TECHNICAL FIELD

The present disclosure relates to an electronic device.

### BACKGROUND ART

Patent Document 1 discloses a semiconductor device including a printed wiring board, a first semiconductor module, a first heat radiating device, a second semiconductor module, and a second heat radiating device, in which the first semiconductor module and the second semiconductor module overlap each other in plan view, and the second semiconductor module is connected in parallel to the first semiconductor module. The first semiconductor module includes a first package body that contains a first semiconductor element, and a first heat radiating surface, provided on one surface of the first package body, that radiates heat generated by the first semiconductor element, and the other surface of the first package body that faces the first heat radiating surface is disposed to face one surface of the printed wiring board. The first heat radiating device is provided on the first heat radiating surface of the first semiconductor module. The second semiconductor module includes a second package body that contains a second semiconductor element and a second heat radiating surface, provided on one surface of the second package body, that radiates heat generated by the second semiconductor element, and the other surface of the second package body that faces the second heat radiating surface is disposed to face the other surface of the printed wiring board. The second heat radiating device is provided on the second heat radiating surface of the second semiconductor module.
Patent Document 1: U.S. Patent Application Publication No. 2019/0157177

### SUMMARY OF THE DISCLOSURE

Patent Document 1 describes heat sinks as examples of the first heat radiating device and the second heat radiating device. According to Patent Document 1, a low-cost semiconductor device having a reduced occupied area and improved heat radiation can be provided.

However, when the heat radiating devices are separately provided for the semiconductor modules installed on both sides of the printed wiring board like the semiconductor device described in Patent Document 1, there is room for improvement in terms of thermal conduction. In addition, since the heat radiating devices are provided on both sides of the printed wiring board, the size and the height of the entire semiconductor device increase. Furthermore, since the size and the weight of devices that include semiconductor devices need to be reduced in recent years, for example, when there is insufficient space on one side of the printed wiring board, the heat radiating devices cannot be easily disposed on both sides of the printed wiring board.

It should be noted that the problems described above are not limited to semiconductor devices but are common problems in electronic devices including electronic components mounted on both sides of the wiring board.

The present disclosure addresses the problems described above with an object of providing an electronic device that has good thermal conductivity and for which the size and the height can be reduced.

An electronic device according to the present disclosure includes: a wiring board having a first main surface and a second main surface that face away from each other in a thickness direction; a first electronic component on the first main surface of the wiring board; a second electronic component on the second main surface of the wiring board; a first heat diffuser plate thermally connected to the first electronic component; a second heat diffuser plate thermally connected to the second electronic component; and a heat conductor extending through the wiring board in the thickness direction and thermally connected to the first heat diffuser plate and the second heat diffuser plate.

According to the present disclosure, an electronic device that has good thermal conductivity and for which the size and the height can be reduced

### BRIEF DESCRIPTION OF THE DRAWINGS

FIG. 1 is a cross-sectional view schematically illustrating an example of an electronic device according to a first embodiment of the present disclosure.

FIG. 2 is a plan view of the electronic device illustrated in FIG. 1 taken along line A.

FIG. 3 is a perspective view schematically illustrating an example of a first heat diffuser plate, a second heat diffuser plate, and a heat conductor.

FIG. 4 is a cross-sectional view schematically illustrating an example of a connection portion between the second heat diffuser plate and the heat conductor.

FIG. 5 is a cross-sectional view schematically illustrating an example of a connection portion between the first heat diffuser plate and the heat conductor.

FIG. 6 is a cross-sectional view schematically illustrating an example of an electronic device according to a second embodiment of the present disclosure.

FIG. 7 is a plan view of the electronic device illustrated in FIG. 6 taken along line B.

FIG. 8 is a cross-sectional view schematically illustrating an example of a capacitor element disposed in a wiring board.

FIG. 9 is a plan view of the capacitor element illustrated in FIG. 8 taken along line C.

### DESCRIPTION OF THE PREFERRED EMBODIMENTS

An electronic device according to the present disclosure will be described below. It should be noted that the present disclosure is not limited to the structure described below, and the structure may be modified as appropriate without the concept of the present disclosure being changed. In addition, the present disclosure also includes combinations of individual preferred structures described below.

It will be appreciated that embodiments illustrated below are only examples, and partial substitutions or combinations of the structures in different embodiments are possible. In the second and subsequent embodiments, descriptions of matters common to the first embodiment are omitted, and only the differences will be described. In particular, the similar effects resulting from the same structure will not be described for each embodiment.

In the following description, when individual embodiments are not particularly distinguished from each other, “the electronic device according to the present disclosure” is used.

In this specification, terms that indicate the relationship between components, such as vertical, parallel, orthogonal and terms that describe the shape of a component do not represent strict meanings but rather indicate a substantially equivalent range that includes differences of, for example, approximately a few percent.

The diagrams illustrated below are schematic, and dimensions, scales of aspect ratios, and the like differ from those of the actual product. In the drawings, the same or corresponding portions are denoted by the same reference numerals. In addition, in the drawings, the same components are denoted by the same reference numerals to omit redundant descriptions.

### First Embodiment

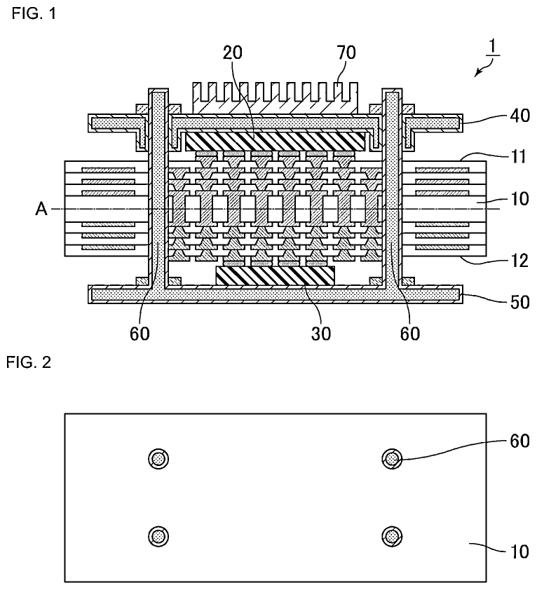

FIG. 1 is a cross-sectional view schematically illustrating an example of an electronic device according to a first embodiment of the present disclosure. FIG. 2 is a plan view of the electronic device illustrated in FIG. 1 taken along line A.

An electronic device 1 illustrated in FIG. 1 includes a wiring board 10, a first electronic component 20, a second electronic component 30, a first heat diffuser plate 40, a second heat diffuser plate 50, and heat conductors 60. As illustrated in FIG. 1, the electronic device 1 preferably further includes a heat radiating fin 70.

The wiring board 10 has a first main surface 11 and a second main surface 12 that face away from each other in a thickness direction (up-down direction in FIG. 1).

The wiring board 10 may be a multilayer board or a single-layer board. In addition, the wiring board 10 may be a ceramic board or a resin board. The ceramic material included in the ceramic board may be either a low-temperature sintered ceramic material or a high-temperature sintered ceramic material. The resin material included in the resin board can be either a thermosetting resin or a thermoplastic resin, such as a glass epoxy resin or a liquid crystal polymer.

In the example illustrated in FIG. 1, the wiring board 10 is a multilayer board that includes a plurality of insulating layers. The wiring board 10 includes wiring conductors, such as an inner conductor provided between the insulating layers, an outer conductor provided on the first main surface 11, an outer conductor provided on the second main surface 12, and a via conductor that passes through the insulating layer in the thickness direction, and specific wiring conductors are electrically connected to the first electronic component 20 or the second electronic component 30.

The first electronic component 20 is mounted on the first main surface 11 of the wiring board 10. For example, the first electronic component 20 may be connected to an outer conductor provided on the first main surface 11 of the wiring board 10 or may be connected to a via conductor exposed to the first main surface 11 of the wiring board 10.

The second electronic component 30 is mounted on the second main surface 12 of the wiring board 10. For example, the second electronic component 30 may be connected to an outer conductor provided on the second main surface 12 of the wiring board 10 or may be connected to a via conductor exposed to the second main surface 12 of the wiring board 10.

The first electronic component 20 and the second electronic component 30 each have a load that generates heat when receiving current.

For example, the first electronic component 20 includes a semiconductor element that executes a logic operation, and the second electronic component 30 includes a voltage regulation circuit that supplies power to the semiconductor element of the first electronic component 20.

The first heat diffuser plate 40 is thermally connected to the first electronic component 20. For example, the first heat diffuser plate 40 is disposed in a direction along the first main surface 11 of the wiring board 10.

The first heat diffuser plate 40 is connected directly or indirectly to the first electronic component 20. For example, the first heat diffuser plate 40 may be connected to the first electronic component 20 via a grease-like or sheet-like thermal interface material (TIM).

As illustrated in FIG. 1, the surface of the first electronic component 20 that is thermally connected to the first heat diffuser plate 40 preferably faces, in the thickness direction, away from the surface of the first electronic component 20 that is electrically connected to the wiring board 10. In the example illustrated in FIG. 1, the surface of the first electronic component 20 that is thermally connected to the first heat diffuser plate 40 is the upper surface, and the surface of the first electronic component 20 that is electrically connected to the wiring board 10 is the lower surface.

The second heat diffuser plate 50 is thermally connected to the second electronic component 30. For example, the second heat diffuser plate 50 is disposed in a direction along the second main surface 12 of the wiring board 10.

The second heat diffuser plate 50 is connected directly or indirectly to the second electronic component 30. For example, the second heat diffuser plate 50 may be connected to the second electronic component 30 via a grease-like or sheet-like TIM.

As illustrated in FIG. 1, the surface of the second electronic component 30 that is thermally connected to the second heat diffuser plate 50 preferably faces, in the thickness direction, away from the surface of the second electronic component 30 that is electrically connected to the wiring board 10. In the example illustrated in FIG. 1, the surface of the second electronic component 30 that is thermally connected to the second heat diffuser plate 50 is the lower surface, and the surface of the second electronic component 30 that is electrically connected to the wiring board 10 is the upper surface.

The heat conductors 60 are provided to pass through the wiring board 10 in the thickness direction and are thermally connected to the first heat diffuser plate 40 and the second heat diffuser plate 50. The heat conductors 60 are disposed obliquely to the first main surface 11 and the second main surface 12 of the wiring board 10 and are preferably disposed orthogonal to the first main surface 11 and the second main surface 12 of the wiring board 10.

Only one heat conductor 60 may be provided, but preferably, two or more heat conductors 60 may be provided. Three or more heat conductors 60 may be provided, and four or more heat conductors 60 may be provided. When two or more heat conductors 60 are provided, the first heat diffuser plate 40 and the second heat diffuser plate 50 can be flat. In addition, when two or more heat conductors 60 are provided, the thermal circulation is excellent. In the example illustrated in FIG. 2, four heat conductors 60 are provided.

In the electronic device 1, the heat conductors 60 can thermally couple the heat radiating structures on both sides of the wiring board 10. Accordingly, for example, by the heat from the second main surface 12 of the wiring board 10 being concentrated on the first main surface 11 and the concentrated heat being radiated from the first main surface 11, the size and the height of the heat radiating structure of the second main surface 12 can be reduced.

For example, at least one of the first heat diffuser plate 40, the second heat diffuser plate 50, and the heat conductor 60 may include a gas-liquid exchange mechanism in the inner space, or each of the first heat diffuser plate 40, the second heat diffuser plate 50, and the heat conductor 60 may include a gas-liquid exchange mechanism in the inner space.

When the first heat diffuser plate 40 includes a gas-liquid exchange mechanism in the inner space, the first heat diffuser plate 40 is preferably a vapor chamber. In this case, although not illustrated in FIG. 1, the first heat diffuser plate 40 preferably includes a capillary structure (wick) disposed in the inner space and a working fluid sealed within the inner space.

When the second heat diffuser plate 50 includes a gas-liquid exchange mechanism in the inner space, the second heat diffuser plate 50 is preferably a vapor chamber. In this case, although not illustrated in FIG. 1, the second heat diffuser plate 50 preferably includes the capillary structure (wick) disposed in the inner space and the working fluid sealed within the inner space.

When each of the heat conductors 60 includes a gas-liquid exchange mechanism in the inner space, the heat conductor 60 is preferably a heat pipe. In this case, although not illustrated in FIG. 1, the heat conductor 60 preferably includes a capillary structure (wick) disposed in the inner space and a working fluid sealed within the inner space.

When each of the first heat diffuser plate 40, the second heat diffuser plate 50, and the heat conductor 60 includes a gas-liquid exchange mechanism in the inner space, the inner space of the heat conductor 60 may communicate with the inner space of the first heat diffuser plate 40 or the second heat diffuser plate 50. In the example illustrated in FIG. 1, the inner space of the heat conductor 60 communicates with the inner space of the second heat diffuser plate 50.

Although not illustrated in FIG. 1, the first heat diffuser plate 40, the second heat diffuser plate 50, and the heat conductors 60 are preferably electrically grounded to the housing (not illustrated) or the wiring board 10 of the electronic device 1.

The electronic device 1 may further include the heat radiating fin 70 thermally connected to the first heat diffuser plate 40, as illustrated in FIG. 1. In this case, since the heat from the second main surface 12 of the wiring board 10 can be concentrated on the first main surface 11 and radiated from the first main surface 11, the heat radiating fin 70 does not need to be disposed on the second main surface 12.

As illustrated in FIG. 1, the surface of the first heat diffuser plate 40 that is thermally connected to the heat radiating fin 70 preferably faces, in the thickness direction, away from the surface of the first heat diffuser plate 40 that is thermally connected to the first electronic component 20. In the example illustrated in FIG. 1, the surface of the first heat diffuser plate 40 that is thermally connected to the heat radiating fin 70 is the upper surface, and the surface of the first heat diffuser plate 40 that is thermally connected to the first electronic component 20 is the lower surface.

When the heat radiating fin 70 is thermally connected to the first heat diffuser plate 40, the heat radiating path closer to the first electronic component 20 is shorter than the heat radiating path closer to the second electronic component 30. Accordingly, the power consumed when current flows through the load of the first electronic component 20 is preferably greater than the power consumed when current flows through the load of the second electronic component 30.

In particular, when each of the first heat diffuser plate 40, the second heat diffuser plate 50, and the heat conductor 60 includes a gas-liquid exchange mechanism in the inner space, the inner space of the heat conductor 60 preferably communicates with the inner space of the second heat diffuser plate 50 to make the heat radiating path closer to the first electronic component 20 shorter than the heat radiating path closer to the second electronic component 30.

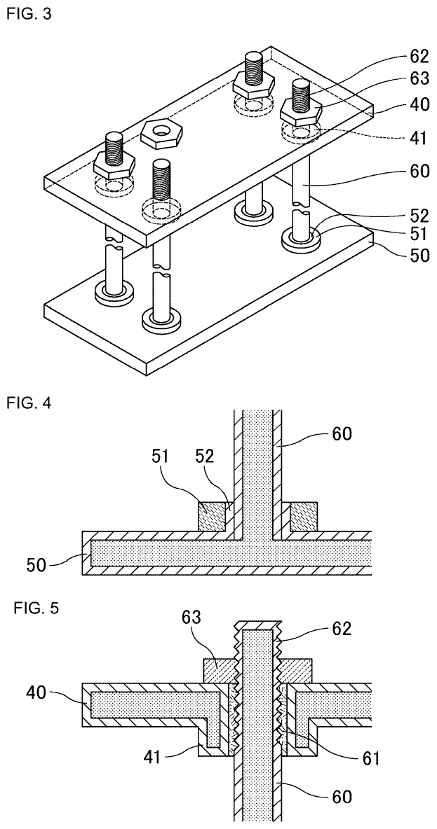

FIG. 3 is a perspective view schematically illustrating an example of the first heat diffuser plate, the second heat diffuser plate, and the heat conductor. FIG. 4 is a cross-sectional view schematically illustrating an example of a connection portion between the second heat diffuser plate and the heat conductor. FIG. 5 is a cross-sectional view schematically illustrating an example of a connection portion between the first heat diffuser plate and the heat conductor.

In the example illustrated in FIGS. 3, 4, and 5, each of the first heat diffuser plate 40, the second heat diffuser plate 50, and the heat conductor 60 includes a gas-liquid exchange mechanism in the inner space. Specifically, the first heat diffuser plate 40 and the second heat diffuser plate 50 are vapor chambers, and the heat conductor 60 is a heat pipe. It should be noted that the capillary structure (wick) and the working fluid are not illustrated in FIGS. 4 and 5.

The materials constituting the first heat diffuser plate 40, the second heat diffuser plate 50, and the heat conductor 60 are not particularly limited, but are preferably metals, such as copper, nickel, aluminum, magnesium, titanium, iron, and alloys containing these metals as a main component, more preferably copper. The materials constituting the first heat diffuser plate 40, the second heat diffuser plate 50, and the heat conductor 60 may be the same or differ partially or completely but preferably the same.

In the example illustrated in FIGS. 3, 4, and 5, the inner space of the heat conductor 60 communicates with the inner space of the second heat diffuser plate 50. For example, one end portion of the heat conductor 60 having a hollow structure is inserted into a cavity provided in the second heat diffuser plate 50. In the connection portion between the second heat diffuser plate 50 and the heat conductor 60, the second heat diffuser plate 50 and the heat conductor 60 may be connected to each other via solder or the like.

As illustrated in FIGS. 3 and 4, a support ring 51 that covers the outer peripheral surface of the heat conductor 60 may be provided in the connection portion between the second heat diffuser plate 50 and the heat conductor 60. In this case, the material constituting the support ring 51 may be, for example, a metal or a non-metal with heat resistance.

As illustrated in FIGS. 3 and 4, the second heat diffuser plate 50 may have a rim portion 52 at the peripheral edge of the cavity. In this case, the inner surface of the rim portion 52 is in contact with the outer peripheral surface of the heat conductor 60. In addition, when the support ring 51 is provided, the outer surface of the rim portion 52 is in contact with the inner surface of the support ring 51.

In the example illustrated in FIGS. 3, 4, and 5, the inner space of the heat conductor 60 does not communicate with the inner space of the first heat diffuser plate 40. For example, one end portion of the heat conductor 41 with a hollow structure is preferably inserted into the cavity provided in the first heat diffuser plate 40.

The heat conductor 41 is, for example, a heat pipe. The material constituting the heat conductor 41 may be the same as or different from the material of the heat conductor 60.

The length of the heat conductor 41 is smaller than the length of the heat conductor 60. On the other hand, the diameter of the heat conductor 41 is greater than the diameter of the heat conductor 60.

The heat conductor 60 is preferably inserted into the hollow portion of the heat conductor 41 integrated with the first heat diffuser plate 40. The thermal contact between the first heat diffuser plate 40 and the heat conductor 60 can be improved by the heat conductor 41 being provided on the first heat diffuser plate 40.

As illustrated in FIG. 5, a thermal interface material (TIM) 61, such as thermal conductive grease, is preferably provided between the heat conductor 60 and the heat conductor 41.

As a result, the thermal contact between the first heat diffuser plate 40 and the heat conductor 60 can be further improved.

As illustrated in FIGS. 3 and 5, the heat conductor 60 may have a thread 62 on the outer peripheral surface. In this case, the heat conductor 60 can be firmly fixed to the first heat diffuser plate 40 by tightening a fixture 63, such as a nut, inserted onto the thread 62 to apply pressure.

As a result, the wiring board 10 is fixed between the first heat diffuser plate 40 and the second heat diffuser plate 50, as illustrated in FIG. 1. For example, by tightening the fixture 63, such as a nut, to press the first heat diffuser plate 40 and the second heat diffuser plate 50, the wiring board 10 can be fixed together with the first electronic component 20 and the second electronic component 30. Alternatively, the first heat diffuser plate 40 or the second heat diffuser plate 50 may be fixed to the wiring board 10 by using metal screws or the like instead of the heat conductors 60. It should be noted that, in FIG. 1, a portion of the heat conductor 41 (see FIGS. 3 and 5) may be present between the wiring board 10 and the heat conductor 60.

### Second Embodiment

An electronic device according to a second embodiment of the present disclosure further includes a capacitor element disposed in the wiring board. In the electronic device according to the second embodiment, the heat conductor is provided to pass through the capacitor element in the thickness direction and is in contact with the capacitor element.

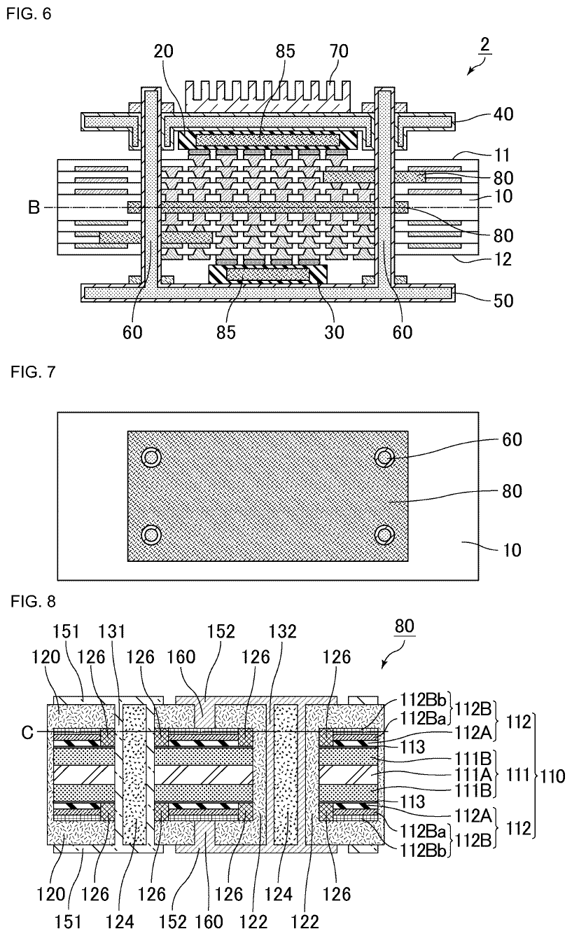

FIG. 6 is a cross-sectional view schematically illustrating an example of the electronic device according to the second embodiment of the present disclosure. FIG. 7 is a plan view of the electronic device illustrated in FIG. 6 taken along line B.

Similar to the electronic device 1 illustrated in FIG. 1, the electronic device 2 illustrated in FIG. 6 includes the wiring board 10, the first electronic component 20, the second electronic component 30, the first heat diffuser plate 40, the second heat diffuser plate 50, and the heat conductors 60. As illustrated in FIG. 6, the electronic device 2 preferably further includes the heat radiating fin 70.

The electronic device 2 further includes the capacitor element 80 disposed in the wiring board 10. As described later, the capacitor element 80 includes the first electrode layer, the second electrode layer, and the dielectric layer, and the first electrode layer and the second electrode layer face each other in the thickness direction with the dielectric layer disposed therebetween.

The disposition of the capacitor element 80 in the wiring board 10 is not particularly limited, but, for example, the capacitor element 80 is disposed in a direction along the first main surface 11 and the second main surface 12 of the wiring board 10. One capacitor element 80 or two or more capacitor elements 80 may be disposed in the wiring board 10. For example, two or more capacitor elements 80 may be disposed in the thickness direction, or two or more capacitor elements 80 may be disposed in the surface direction.

The heat conductors 60 are provided to pass through the capacitor element 80 in the thickness direction and are in contact with the capacitor element 80.

When two or more heat conductors 60 are provided, at least one of the heat conductors 60 may pass through the capacitor element 80 in the thickness direction. In the example illustrated in FIG. 7, four heat conductors 60 pass through the capacitor element 80 in the thickness direction.

When two or more capacitor elements 80 are disposed in the wiring board 10, the number of heat conductors 60 that pass through the capacitor elements 80 may be the same as each other or may differ from each other between some or all of the heat conductors 60. In addition, a capacitor element 80 through which the heat conductor 60 does not pass may be present.

In the electronic device 2, since the heat conductor 60 passes through the capacitor element 80 disposed in the wiring board 10, there is no interference with the heat radiating structures on both sides of the wiring board 10. In addition, the heat generated by the capacitor element 80 can be radiated through the heat conductor 60.

Furthermore, since the capacitor elements 80 are disposed in the wiring board 10, the capacitor elements disposed on the second main surface 12 of the wiring board 10 can be reduced. Accordingly, on the second main surface 12 of the wiring board 10, the size and the height of the heat radiating structure can be further reduced.

As illustrated in FIG. 6, the electronic device 2 may further include a capacitor element 85 disposed in the first electronic component 20 or the second electronic component 30. The capacitor element 85 may be disposed in either the first electronic component 20 or the second electronic component 30 or may be disposed in each of the first electronic component 20 and the second electronic component 30.

Like the capacitor element 80, the capacitor element 85 includes the first electrode layer, the second electrode layer, and the dielectric layer, and the first electrode layer and the second electrode layer face each other in the thickness direction with the dielectric layer disposed therebetween. The structure of the capacitor element 85 may be the same as or different from the structure of the capacitor element 80.

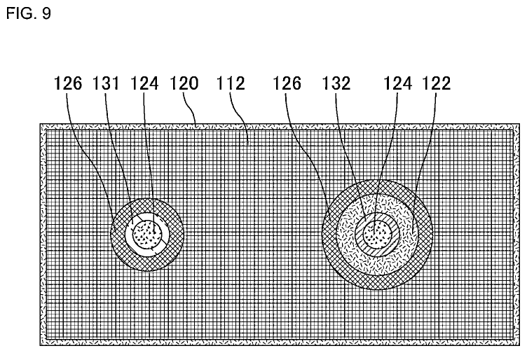

FIG. 8 is a cross-sectional view schematically illustrating an example of the capacitor element disposed in the wiring board. FIG. 9 is a plan view of the capacitor element illustrated in FIG. 8 taken along line C.

The capacitor element 80 illustrated in FIG. 8 includes a capacitor unit 110 and a sealing layer 120 that seals the capacitor unit 110.

The capacitor unit 110 includes the first electrode layer and the second electrode layer that face each other in the thickness direction with the dielectric layer disposed therebetween.

In the example illustrated in FIG. 8, the first electrode layer is an anode plate 111, and the second electrode layer is a cathode layer 112. As a result, the capacitor unit 110 constitutes an electrolytic capacitor.

The anode plate 111 includes, for example, a core portion 111A made of a metal and a porous portion 111B provided on at least one main surface of the core portion 111A. A dielectric layer 113 is provided on the surface of the porous portion 111B, and the cathode layer 112 is provided on the surface of the dielectric layer 113.

The cathode layer 112 includes, for example, a solid electrolyte layer 112A provided on the surface of the dielectric layer 113. The cathode layer 112 preferably further includes a conductive layer 112B provided on the surface of the solid electrolyte layer 112A. The conductive layer 112B includes, for example, a carbon layer 112Ba provided on the surface of the solid electrolyte layer 112A and a copper layer 112Bb provided on the surface of the carbon layer 112Ba.

It should be noted that the capacitor unit 110 is not limited to an electrolytic capacitor, such as a solid electrolytic capacitor, but the capacitor unit 110 may also form a capacitor such as, for example, a ceramic capacitor including barium titanate or the like, or a thin film capacitor including silicon nitride (SiN), silicon dioxide (SiO₂), hydrogen fluoride (HF), or the like. However, in terms of formation of a thinner capacitor unit 110 with a relatively larger area and mechanical properties, such as rigidity and flexibility of the capacitor element 80, the capacitor unit 110 preferably forms a capacitor including a metal, such as aluminum, as a base material, more preferably forms an electrolytic capacitor including a metal, such as aluminum, as a base material.

As illustrated in FIGS. 8 and 9, the capacitor element 80 preferably includes a first through-hole conductor 131 electrically connected to the first electrode layer (the anode plate 111 in the example illustrated in FIG. 8).

In addition, the capacitor element 80 preferably includes a second through-hole conductor 132 electrically connected to the second electrode layer (the cathode layer 112 in the example illustrated in FIG. 8).

In the example illustrated in FIGS. 8 and 9, the side wall of the first through-hole conductor 131 is electrically connected to the end face of the first electrode layer (for example, the anode plate 111). The space between the second through-hole conductor 132 and the capacitor unit 110 is filled with an insulating material 122.

A resin filling portion 124 may be provided inside the first through-hole conductor 131. Similarly, the resin filling portion 124 may be provided inside the second through-hole conductor 132. It should be noted that the resin filling portion 124 may be a conductor or an insulator.

As illustrated in FIGS. 8 and 9, an insulating layer 126 is preferably provided around the first through-hole conductor 131. Similarly, the insulating layer 126 is preferably provided around the second through-hole conductor 132. In the example illustrated in FIGS. 8 and 9, the insulating layer 126 is provided between the first through-hole conductor 131 and the cathode layer 112 or between the second through-hole conductor 132 and the cathode layer 112.

The first through-hole conductor 131 is formed, for example, as described below. First, a first through-hole that passes through the capacitor unit 110 and the sealing layer 120 in the thickness direction is formed by performing drilling, laser machining, or the like. Then, the first through-hole conductor 131 is formed by the inner wall surface of the first through-hole being metalized with a metal material containing a low-resistance metal, such as copper, gold, or silver. When the first through-hole conductor 131 is formed, machining becomes easier by, for example, metallizing the inner wall surface of the first through-hole by electroless copper plating treatment, electrolytic copper plating treatment, or the like. It should be noted that the method of forming the first through-hole conductor 131 may be a method that fills the first through-hole with a metal material or a composite material of a metal and a resin, in addition to a method that metallizes the inner wall surface of the first through-hole.

The second through-hole conductor 132 is formed, for example, as described below. First, a first through-hole that passes through the capacitor unit 110 in the thickness direction is formed by performing drilling, laser machining, or the like. Next, the first through-hole described above is filled with the insulating material 122. A second through-hole is formed by performing drilling, laser machining, or the like on the portion filled with insulating material 122. At this time, the diameter of the second through-hole is made smaller than the diameter of the first through-hole filled with insulating material 122, so that the insulating material 122 is present between the inner wall surface of the previously formed first through-hole and the inner wall surface of the second through-hole in the surface direction. After that, the inner wall surface of the second through-hole is metallized with a metal material containing a low-resistance metal, such as copper, gold, or silver, to form the second through-hole conductor 132. When the second through-hole conductor 132 is formed, for example, the inner wall surface of the second through-hole metalized by electroless copper plating treatment, electrolytic copper plating treatment, or the like to make machining easy. It should be noted that the method of forming the second through-hole conductor 132 may be a method that fills the second through-hole with a metal material or a composite material of a metal and a resin, in addition to a method that metallizes the inner wall surface of the second through-hole.

Although not illustrated in FIG. 8, the capacitor element 80 may further include a through-hole conductor other than the first through-hole conductor 131 and the second through-hole conductor 132. For example, the capacitor element 80 may further include a through-hole conductor electrically connected to none of the first electrode layer and the second electrode layer of the capacitor unit 110.

The capacitor element 80 preferably further includes outer wiring layers 151 and 152 provided on the surface of the sealing layer 120. The outer wiring layers 151 and 152 are preferably provided along the main surface direction orthogonal to the thickness direction of the capacitor unit 110. The outer wiring layers 151 and 152 are provided on both main surfaces of the capacitor unit 110 in the example illustrated in FIG. 8, but the outer wiring layers 151 and 152 may also be provided on only one main surface.

The capacitor element 80 preferably further includes a via conductor 160 provided in the sealing layer 120. The via conductor 160 is preferably provided along the thickness direction of the capacitor unit 110. One end of the via conductor 160 is connected to the second electrode layer (for example, the cathode layer 112) of the capacitor unit 110, and the other end is connected to the outer wiring layer 152.

In the example illustrated in FIG. 8, the first electrode layer (for example, the anode plate 111) of the capacitor unit 110 is electrically connected to the outer wiring layer 151 via the first through-hole conductor 131. As described above, the first electrode layer is preferably electrically connected to the surface of the sealing layer 120 via the first through-hole conductor 131. The outer wiring layer 151 can function as a connection terminal of the capacitor unit 110.

In the example illustrated in FIG. 8, the second through-hole conductor 132 is electrically connected to the second electrode layer (for example, the cathode layer 112) of the capacitor unit 110 via the outer wiring layer 152 and the via conductor 160. As described above, the second through-hole conductor 132 is preferably provided to pass through both the capacitor unit 110 and the sealing layer 120 in the thickness direction of the capacitor unit 110. The outer wiring layer 152 can function as a connection terminal of the capacitor unit 110.

When the capacitor unit 110 includes the anode plate 111 and the cathode layer 112, the anode plate 111 preferably includes a so-called valve metal that serves as a valve. The valve metals can be, for example, a metal, such as aluminum, tantalum, niobium, titanium, or zirconium, or an alloy containing at least one of these metals. Among these, aluminum or an aluminum alloy is preferable.

The shape of the anode plate 111 is preferably planar, more preferably foil-like. The anode plate 111 only needs to have the porous portion 111B on at least one main surface of the core portion 111A and may also have the porous portions 111B on both main surfaces of the core portion 111A. The porous portion 111B is preferably a porous layer formed on the surface of the core portion 111A, more preferably an etching layer.

The thickness of the anode plate 111 before etching treatment is preferably 60 μm to 200 μm. The thickness of the unetched core portion 111A after etching treatment is preferably 15 μm to 70 μm. The thickness of the porous portion 111B is designed according to the required withstand voltage and the electrostatic capacity, and the thickness including the porous portions 111B on both sides of the core portion 111A is preferably 10 μm to 180 μm.

The pore diameter of the porous portion 111B is preferably 10 nm to 600 nm. It should be noted that the pore diameter of the porous portion 111B refers to a median diameter D50 measured by a mercury porosimeter. The pore diameter of the porous portion 111B can be controlled by, for example, adjusting various conditions of etching.

The dielectric layer 113 provided on the surface of the porous portion 111B is porous by reflecting the surface condition of the porous portion 111B and has a finely uneven surface. The dielectric layer 113 is preferably made from an oxide film of one of the valve metals described above. For example, when aluminum foil is used as the anode plate 111, the dielectric layer 113 made from an oxide film can be formed by performing anodic oxidation treatment (also referred to as chemical conversion treatment) on the surface of the aluminum foil in an aqueous solution containing ammonium adipate or the like.

The thickness of the dielectric layer 113 is designed according to the required withstand voltage and the electrostatic capacity and is preferably 10 nm to 100 nm.

When the cathode layer 112 includes the solid electrolyte layer 112A, the material constituting the solid electrolyte layer 112A can be, for example, conductive polymers, such as polypyrroles, polythiophenes, or polyanilines. Among these, polythiophenes are preferable, and poly (3,4-ethylenedioxythiophene), which is referred to as PEDOT, is more preferable. In addition, the conductive polymer described above may contain a dopant, such as polystyrenesulfonic acid (PSS). It should be noted that the solid electrolyte layer 112A preferably includes an inner layer with which the pores (recesses) of the dielectric layer 113 are embedded and an outer layer that covers the dielectric layer 113.

The thickness of the solid electrolyte layer 112A from the surface of the porous portion 111B is preferably 2 μm to 20 μm.

The solid electrolyte layer 112A is formed by, for example, a method that forms a polymer film, such as poly (3,4-ethylenedioxythiophene) on the surface of the dielectric layer 113 by using a treatment liquid containing a monomer, such as 3,4-ethylenedioxythiophene, or a method that applies a dispersion liquid of polymers, such as poly(3,4-ethylenedioxythiophene) onto the surface of the dielectric layer 113 and dries the dispersion liquid.

The solid electrolyte layer 112A can be formed in a predetermined region by applying the treatment liquid or dispersion liquid onto the surface of the dielectric layer 113 by using a method, such as sponge transfer, screen printing, dispenser coating, or inkjet printing.

When the cathode layer 112 includes the conductive layer 112B, the conductive layer 112B includes at least one of the conductive resin layer and the metal layer. The conductive layer 112B may include only the conductive resin layer or only the metal layer. The conductive layer 112B preferably covers the entire surface of the solid electrolyte layer 112A.

The conductive resin layer can be, for example, a conductive adhesive layer containing at least one conductive filler selected from the group consisting of silver filler, copper filler, nickel filler, and carbon filler.

The metal layer can be, for example, a metal plating film, metal foil, or the like. The metal layer is preferably made of at least one metal selected from the group consisting of nickel, copper, silver, and alloys containing these metals as main components. It should be noted that the term main component refers to the element component with the largest weight ratio.

When the conductive layer 112B includes the carbon layer 112Ba and the copper layer 112Bb, the carbon layer 112Ba is provided to electrically and mechanically connect the solid electrolyte layer 112A and the copper layer 112Bb to each other. The carbon layer 112Ba can be formed in a predetermined region by applying a carbon paste onto the solid electrolyte layer 112A by using a method, such as sponge transfer, screen printing, dispenser coating, or inkjet printing. It should be noted that the copper layer 112Bb is preferably laminated on the carbon layer 112Ba in the next process when the carbon layer 112Ba is viscous before being dried. The thickness of the carbon layer 112Ba is preferably 2 μm to 20 μm.

When the conductive layer 112B includes the carbon layer 112Ba and the copper layer 112Bb, the copper layer 112Bb can be formed by applying a copper paste onto the carbon layer 112Ba by using a method, such as sponge transfer, screen printing, spray coating, dispenser application, or inkjet printing. The thickness of the copper layer 112Bb is preferably 2 μm to 20 μm.

The sealing layer 120 is made of an insulating material. The sealing layer 120 is preferably made of an insulating resin. The insulating resin that constitutes the sealing layer 120 can be, for example, an epoxy resin, a phenolic resin, or the like. In addition, the sealing layer 120 preferably contains filler. The filler contained in the sealing layer 120 can be inorganic filler, such as silica particles, alumina particles, or metal particles.

The sealing layers 120 are provided on both main surfaces of the capacitor unit 110 in the example illustrated in FIG. 8, but the sealing layer 120 may also be provided on only one main surface. The sealing layer 120 provided on one main surface of the capacitor unit 110 may include one layer or two or more layers. When the sealing layer 120 includes two or more layers, the materials constituting these layers may be the same or different.

A layer such as, for example, a stress relief layer or a moisture-proof film may be provided between the capacitor unit 110 and the sealing layer 120.

The stress relief layer is preferably made of an insulating resin. The insulating resin that constitutes the stress relief layer can be, for example, an epoxy resin, a phenolic resin, a silicone resin, or the like. In addition, the stress relief layer preferably contains filler. The filler contained in the stress relief layer can be inorganic filler, such as silica particles, alumina particles, or metal particles. The insulating resin constituting the stress relief layer is preferably different from the insulating resin constituting the sealing layer 120.

The sealing layer 120 needs to have characteristics, such as adhesiveness to the outer electrodes (for example, the outer wiring layers 151 and 152), as an outer body, and accordingly, it is difficult to simply match the coefficient of linear expansion with that of the capacitor unit 110 or to select a resin with an arbitrary elasticity. In contrast, by providing a stress relief layer, it is possible to adjust the thermal stress design without losing the individual functions of the capacitor unit 110 and the sealing layer 120.

The stress relief layer preferably has lower moisture permeability than the sealing layer 120. In this case, the infiltration of moisture to the capacitor unit 110 can be reduced in addition to adjustment of the stress. The moisture permeability of the stress relief layer can be adjusted by the type of the insulating resin that constitutes the stress relief layer, the amount of filler contained in the stress relief layer, and the like.

The insulating material 122 with which the space between the second through-hole conductor 132 and the capacitor unit 110 is filled preferably includes an insulating resin. The insulating resin included in the insulating material 122 can be, for example, epoxy resin, phenolic resin, or the like. In addition, the insulating material 122 preferably contains filler. The filler contained in the insulating material 122 can be, for example, inorganic filler, such as silica particles, alumina particles, or metal particles.

The insulating material 122 may be made of the same material as the sealing layer 120. For example, as illustrated in FIG. 8, the space between the second through-hole conductor 132 and the capacitor unit 110 may be embedded with the sealing layer 120.

Alternatively, the insulating material 122 may be made of the same material as the stress relief layer described above. For example, when the capacitor element 80 includes the stress relief layer, the space between the second through-hole conductor 132 and the capacitor unit 110 may be embedded with the stress relief layer.

The insulating material 122 may have a thermal expansion coefficient that is greater than, less than, or equal to that of the material (for example, copper) constituting the first through-hole conductor 131 or the second through-hole conductor 132.

When the resin filling portion 124 is provided inside the first through-hole conductor 131 or the second through-hole conductor 132, the material constituting the resin filling portion 124 may have a thermal expansion coefficient that is greater than, less than, or equal to that of the material (for example, copper) constituting the first through-hole conductor 131 or the second through-hole conductor 132.

When the insulating layer 126 is provided around the first through-hole conductor 131 or the second through-hole conductor 132, the insulating layer 126 is preferably made of an insulating resin. The insulating resin that constitutes the insulating layer 126 can be polyphenylsulfone resin, polyether sulfone resin, cyanate ester resin, fluororesin (such as, tetrafluoroethylene, tetrafluoroethylene-perfluoroalkyl vinyl ether copolymer), polyimide resin, polyamide-imide resin, epoxy resin, or a derivative or precursor of these resins.

The insulating layer 126 may be made of the same resin as the sealing layer 120. Unlike the sealing layer 120, since inorganic filler contained in the insulating layer 126 may adversely affect the effective capacitance of the capacitor unit 110, the insulating layer 126 is preferably made of only resin.

The insulating layer 126 can be formed by applying a mask material, such as composition containing insulating resin, onto the surface of the porous portion 111B by using a method, such as sponge transfer, screen printing, dispenser coating, or inkjet printing.

The thickness of the insulating layer 126 from the surface of the porous portion 111B is preferably 20 μm or less. The thickness of the insulating layer 126 from the surface of the porous portion 111B may be 0 μm but is preferably 2 μm or more.

The inside of the porous portion 111B may be embedded with the insulating layer 126, and the insulating layer 126 may be provided on the surface of the porous portion 111B above the filled portion. That is, the thickness of the insulating layer 126 may be greater than the thickness of the porous portion 111B.

An anode connection layer may be provided between the first through-hole conductor 131 and the end face of the anode plate 111. That is, the first through-hole conductor 131 may be electrically connected to the end face of the anode plate 111 via the anode connection layer. When the anode connection layer is provided between the first through-hole conductor 131 and the end face of the anode plate 111, the anode connection layer functions as a barrier layer against the anode plate 111. As a result, since dissolution of the anode plate 111 that occurs during treatment of chemical solution for forming the wiring layer, such as the outer wiring layer 151, is suppressed, infiltration of the chemical solution to the capacitor unit 110 is prevented, and the reliability of the capacitor element 80 is improved.

When the anode connection layer is provided between the first through-hole conductor 131 and the end face of the anode plate 111, the anode connection layer includes, in the order from the anode plate 111, for example, a first anode connection layer mainly including zinc and a second anode connection layer mainly including nickel or copper. For example, after the first anode connection layer is formed on the end face of the anode plate 111 by substitution deposition of zinc using zincate treatment, the second anode connection layer is formed on the first anode connection layer by electroless nickel plating treatment or electroless copper plating treatment. It should be noted that the first anode connection layer may disappear, and in this case, the anode connection layer may include only the second anode connection layer.

It should be noted that the anode connection layer does not need to be provided between the first through-hole conductor 131 and the end face of the anode plate 111. In this case, the first through-hole conductor 131 may be directly connected to the end face of the anode plate 111.

As illustrated in FIG. 9, the first through-hole conductor 131 is preferably electrically connected to the end face of the first electrode layer (for example, the anode plate 111) over the entire circumference. In this case, since the contact area between the first through-hole conductor 131 and the first electrode layer increases and the connection resistance with respect to the first through-hole conductor 131 reduces, the equivalent series resistance (ESR) of the capacitor element 80 can be reduced.

In addition, since the adhesiveness between the first through-hole conductor 131 and the first electrode layer is improved, problems, such as peeling at the connection surface caused by thermal stress, are less likely to occur.

The constituent materials of the outer wiring layers 151 and 152 can be low-resistance metals, such as silver, gold, and copper. The constituent material of the outer wiring layer 151 may be the same as or different from the constituent material of the outer wiring layer 152. The outer wiring layers 151 and 152 are formed by, for example, a method, such as plating treatment.

A mixed material of a resin and at least one conductive filler selected from the group consisting of silver filler, copper filler, nickel filler, and carbon filler may be provided as the constituent materials of the outer wiring layers 151 and 152 to improve the adhesiveness between the outer wiring layer 151 or 152 and another component, for example, the adhesiveness between the outer wiring layer 151 and the first through-hole conductor 131 or the adhesiveness between the outer wiring layer 152 and the second through-hole conductor 132.

The constituent material of the via conductor 160 can be a low-resistance metal, such as silver, gold, or copper. The via conductor 160 is formed by a method such as, for example, plating treatment or thermal treatment of a conductive paste.

In the capacitor element 80, one capacitor unit 110 or a plurality of capacitor units 110 may be disposed in the sealing layer 120.

When the plurality of capacitor units 110 are disposed in the sealing layer 120, adjacent capacitor units 110 only need to be physically separated from each other. Accordingly, adjacent capacitor units 110 may be electrically separated from each other or may be electrically connected to each other. The portion by which adjacent capacitor units 110 are separated from each other is preferably filled with an insulating material, such as the sealing layer 120. The spacing between adjacent capacitor units 110 may be constant in the thickness direction or may decrease in the thickness direction.

When the plurality of capacitor units 110 are disposed in the sealing layer 120, the plurality of capacitor units 110 may be disposed to be arranged in the surface direction, may be disposed to be laminated in the thickness direction, or may be disposed to be arranged in the surface direction and to be laminated in the thickness direction. The plurality of capacitor units 110 may be disposed in a regular pattern or in an irregular pattern. The sizes and the shapes of the capacitor units 110 may be the same as each other or may be partially or fully different from each other. The structures of the capacitor units 110 are preferably the same, but the capacitor units 110 with different structures may be included.

The capacitor element 80 can be suitably used as the constituent material of a composite electronic component. Such composite electronic components include, for example, the capacitor element 80, the outer electrode (for example, the outer wiring layer), provided outside the capacitor element 80 (for example, outside the sealing layer), that is electrically connected to the first electrode layer and the second electrode layer of the capacitor element 80, and an electronic component connected to the outer electrode described above.

The electronic component connected to the outer electrode of the composite electronic component can be either a passive element or an active element. Both the passive element and the active element may be connected to the outer electrode, or either the passive element or the active element may be connected to the outer electrode. In addition, a composite body of the passive element and the active element may be connected to the outer electrode.

The passive element can be, for example, an inductor or the like. The active element can be a memory, a graphical processing unit (GPU), a central processing unit (CPU), a micro processing unit (MPU), a power management IC (PMIC), or a like.

The capacitor element 80 has a sheet-like shape as a whole. Accordingly, in the composite electronic component, the capacitor element 80 can be used as a mounting board, and electronic components can be mounted on the capacitor element 80. In addition, when the shape of electronic components mounted on the capacitor element 80 is sheet-like, the capacitor element 80 and the electronic components can be connected to each other in the thickness direction via a through-hole conductor that passes through the electronic components in the thickness direction. As a result, the active element and passive element can be formed as an integrated module.

For example, a switching regulator can be formed by the capacitor element 80 being electrically connected between a voltage regulator including a semiconductor active element and a load to which converted DC voltage is supplied.

In the composite electronic component, after a circuit layer is formed on one surface of a capacitor matrix sheet on which a plurality of capacitor elements 80 are further laid out, connection to either a passive element or an active element may be made.

Alternatively, after the capacitor element 80 is disposed in a cavity portion provided in advance in the board and the cavity portion is embedded with a resin, the circuit layer may be formed on the resin. Another electronic component (passive element or active element) may be installed in another cavity portion of this board.

Alternatively, after the capacitor element 80 is mounted on a smooth carrier, such as a wafer or glass, and an outer layer portion of resin is formed, a circuit layer may be formed, and connection to a passive element or an active element may be made.

### OTHER EMBODIMENTS

The electronic device according to the present disclosure is not limited to the embodiments described above, and various applications and modifications can be made to the structure, the manufacturing conditions, and the like of the electronic device within the scope of the present disclosure.

This specification discloses the following content.

<1> An electronic device comprising: a wiring board having a first main surface and a second main surface that face away from each other in a thickness direction; a first electronic component on the first main surface of the wiring board; a second electronic component on the second main surface of the wiring board; a first heat diffuser plate thermally connected to the first electronic component; a second heat diffuser plate thermally connected to the second electronic component; and a heat conductor extending through the wiring board in the thickness direction and thermally connected to the first heat diffuser plate and the second heat diffuser plate.

<2> The electronic device according to <1>, wherein at least one of the first heat diffuser plate, the second heat diffuser plate, and the heat conductor includes a gas-liquid exchange mechanism in an inner space thereof.

<3> The electronic device according to <1> or <2>, wherein each of the first heat diffuser plate, the second heat diffuser plate, and the heat conductor includes a gas-liquid exchange mechanism in an inner space thereof.

<4> The electronic device according to <3>, wherein the inner space of the heat conductor communicates with the inner space of the first heat diffuser plate or the second heat diffuser plate.

<5> The electronic device according to any one of <1> to <4>, further comprising: a heat radiating fin thermally connected to the first heat diffuser plate.

<6> The electronic device according to <5>, wherein the electronic device is structured such that power consumed when current flows through a load of the first electronic component is greater than power consumed when current flows through a load of the second electronic component.

<7> The electronic device according to <5> or <6>, wherein each of the first heat diffuser plate, the second heat diffuser plate, and the heat conductor includes a gas-liquid exchange mechanism in an inner space, and the inner space of the heat conductor communicates with the inner space of the second heat diffuser plate.

<8> The electronic device according to any one of <1> to <7>, wherein a surface of the first electronic component that is thermally connected to the first heat diffuser plate faces away from a surface of the first electronic component that is electrically connected to the wiring board in the thickness direction, and a surface of the second electronic component that is thermally connected to the second heat diffuser plate faces away from a surface of the second electronic component that is electrically connected to the wiring board in the thickness direction.

<9> The electronic device according to any one of <1> to <8>, wherein the heat conductor is a first heat conductor, and the electronic device further comprises at least a second heat conductor that extends through the wiring board in the thickness direction and is thermally connected to the first heat diffuser plate and the second heat diffuser plate.

<10> The electronic device according to any one of <1> to <9>, wherein the heat conductor has a thread on an outer peripheral surface thereof.

<11> The electronic device according to any one of <1> to <10>, wherein the first heat diffuser plate, the second heat diffuser plate, and the heat conductor are electrically grounded to a housing or the wiring board of the electronic device.

<12> The electronic device according to any one of <1> to <11>, wherein the first electronic component includes a semiconductor element that executes a logic operation, and the second electronic component includes a voltage regulation circuit that supplies power to the semiconductor element of the first electronic component.

<13> The electronic device according to any one of <1> to <12>, further comprising: a capacitor element in the wiring board, and wherein the capacitor element includes a first electrode layer, a second electrode layer, and a dielectric layer, and the first electrode layer and the second electrode layer face each other in the thickness direction with the dielectric layer therebetween, and the heat conductor extends through the capacitor element in the thickness direction and is in contact with the capacitor element.

<14> The electronic device according to <13>, wherein the first electrode layer is an anode plate including a core portion made of a metal and a porous portion on at least one main surface of the core portion, the dielectric layer is on a surface of the porous portion, and the second electrode layer is a cathode layer on a surface of the dielectric layer.

### REFERENCE SIGNS LIST

1, 2 electronic device
10 wiring board
11 first main surface
12 second main surface
20 first electronic component
30 second electronic component
40 first heat diffuser plate
41 heat conductor
50 second heat diffuser plate
51 support ring
52 rim portion
60 heat conductor
61 TIM
62 thread
63 fixture
70 heat radiating fin
80, 85 capacitor element
110 capacitor unit
111 anode plate
111A core portion
111B porous portion
112 cathode layer
112A solid electrolyte layer
112B conductive layer
112Ba carbon layer
112Bb copper layer
113 dielectric layer
120 sealing layer
122 insulating material
124 resin filling portion
126 insulating layer
131 first through-hole conductor
132 second through-hole conductor
151, 152 outer wiring layer
160 via conductor

1. An electronic device comprising:
a wiring board having a first main surface and a second main surface that face away from each other in a thickness direction;
a first electronic component on the first main surface of the wiring board;
a second electronic component on the second main surface of the wiring board;
a first heat diffuser plate thermally connected to the first electronic component;
a second heat diffuser plate thermally connected to the second electronic component; and
a heat conductor extending through the wiring board in the thickness direction and thermally connected to the first heat diffuser plate and the second heat diffuser plate.

2. The electronic device according to claim 1, wherein at least one of the first heat diffuser plate, the second heat diffuser plate, and the heat conductor includes a gas-liquid exchange mechanism in an inner space thereof.

3. The electronic device according to claim 1, wherein each of the first heat diffuser plate, the second heat diffuser plate, and the heat conductor includes a gas-liquid exchange mechanism in an inner space thereof.

4. The electronic device according to claim 3, wherein the inner space of the heat conductor communicates with the inner space of the first heat diffuser plate or the second heat diffuser plate.

5. The electronic device according to claim 3, wherein the inner space of the heat conductor does not communicate with the inner space of the first heat diffuser plate and communicates with the inner space of the second heat diffuser plate.

6. The electronic device according to claim 1, further comprising:
a heat radiating fin thermally connected to the first heat diffuser plate.

7. The electronic device according to claim 6, wherein the electronic device is structured such that power consumed when current flows through a load of the first electronic component is greater than power consumed when current flows through a load of the second electronic component.

8. The electronic device according to claim 6, wherein each of the first heat diffuser plate, the second heat diffuser plate, and the heat conductor includes a gas-liquid exchange mechanism in an inner space thereof.

9. The electronic device according to claim 6, the inner space of the heat conductor communicates with the inner space of the second heat diffuser plate.

10. The electronic device according to claim 1,
wherein a surface of the first electronic component that is thermally connected to the first heat diffuser plate faces away from a surface of the first electronic component that is electrically connected to the wiring board in the thickness direction, and
a surface of the second electronic component that is thermally connected to the second heat diffuser plate faces away from a surface of the second electronic component that is electrically connected to the wiring board in the thickness direction.

11. The electronic device according to claim 1, wherein the heat conductor is a first heat conductor, and the electronic device further comprises at least a second heat conductor that extends through the wiring board in the thickness direction and is thermally connected to the first heat diffuser plate and the second heat diffuser plate.

12. The electronic device according to claim 1, wherein the heat conductor has a thread on an outer peripheral surface thereof.

13. The electronic device according to claim 12, wherein the heat conductor is fixed to the first heat diffuser plate at the thread.

14. The electronic device according to claim 1, wherein the first heat diffuser plate, the second heat diffuser plate, and the heat conductor are electrically grounded to a housing or the wiring board of the electronic device.

15. The electronic device according to claim 1, wherein the first electronic component includes a semiconductor element that executes a logic operation, and the second electronic component includes a voltage regulation circuit that supplies power to the semiconductor element of the first electronic component.

16. The electronic device according to claim 1, further comprising:
a capacitor element in the wiring board,
wherein the capacitor element includes a first electrode layer, a second electrode layer, and a dielectric layer, and the first electrode layer and the second electrode layer face each other in the thickness direction with the dielectric layer therebetween.

17. The electronic device according to claim 16, wherein the heat conductor extends through the capacitor element in the thickness direction and is in contact with the capacitor element.

18. The electronic device according to claim 16,
wherein the first electrode layer is an anode plate including a core portion made of a metal and a porous portion on at least one main surface of the core portion,
the dielectric layer is on a surface of the porous portion, and
the second electrode layer is a cathode layer on a surface of the dielectric layer.
